(19) United States
(12) Patent Application Publication
(10) Pub. No.: US 2012/0008306 A1
(43) Pub. Date: Jan. 12, 2012

(54) LIGHT EMITTING MODULE AND LAMP UNIT

(75) Inventors: Yasutaka Sasaki, Shizuoka (JP); Masanobu Mizuno, Shizuoka (JP); Yasuaki Tsutsumi, Shizuoka (JP); Shogo Sugimori, Shizuoka (JP); Kazuhiro Ito, Shizuoka (JP)

(73) Assignee: KOITO MANUFACTURING CO., LTD., Tokyo (JP)

(21) Appl. No.: 13/256,205

(22) PCT Filed: Mar. 11, 2010
(86) PCT No.: PCT/JP2010/001746

§ 371 Date: Sep. 21, 2011

(30) Foreign Application Priority Data
Mar. 13, 2009 (JP) 2009-062037

(51) Int. Cl. F21V 9/16; H01L 33/50

(52) U.S. Cl. 362/84; 257/98; 257/E33.067

(57) ABSTRACT

In a light emitting module 40, a semiconductor light emitting element 48 is configured by forming an electrode pattern to which a current for light emission is supplied on the light emitting surface 48a. A light wavelength conversion member 52 is formed to be transparent and to convert the wavelength of the light emitted by the semiconductor light emitting element 48 and to emit the light from the emitting surface 52a. In the light wavelength conversion member 52, a plurality of protruding portions 52b are provided on the emitting surface 52a at an arrangement interval smaller than the repeating pattern interval in the electrode pattern. Each of the plurality of protruding portions 52b is formed into a hemispherical shape. In addition, the plurality of protruding portions 52b are provided on the emitting surface 52a at an arrangement interval of 300 μm or less.

### FIELD OF THE INVENTION

The present invention relates to a light emitting module and a lamp unit comprising the light emitting module.

### BACKGROUND ART

In recent years, for the purpose of long life or reduction in power consumption, techniques have been developed in each of which a light emitting module having a light emitting element, such as an LED (Light Emitting Diode), is adopted as a light source for emitting strong light, such as a lamp unit that emits light toward the front of a vehicle. However, the light emitting module to be used in such an application is required not only to achieve white light emission but also to have high luminance and high light intensity. Accordingly, in order to, for example, the extraction efficiency of while light, a lighting system comprising: a light emitting element mainly emitting blue light; a yellow phosphor mainly emitting yellow light by being excited with the blue light; and a blue-transmitting yellow-reflecting means that transmits the blue light from the light emitting element and reflects the light with a wavelength of the yellow light or more from the yellow phosphor, is proposed (see, for example, Patent Document 1). In addition, in order to enhance, for example, a conversion efficiency, a structure comprising a ceramic layer arranged within the channel of the light emitted by a light emitting layer is proposed (see, for example, Patent Document 2).

[Patent Document 1] Japanese Patent Application Publication No. 2007-59864

[Patent Document 2] Japanese Patent Application Publication No. 2006-5367

### DISCLOSURE OF THE INVENTION

### Problems to be Solved by the Invention

When it is required to achieve high illuminance and light intensity of the light emitted by a light emitting module while converting the wavelength of the light, as in the case where the light emitting module is used, for example, in the aforementioned lamp unit, it becomes a major challenge to enhance the extraction efficiency of the light from the light emitting module. However, when an incident angle of light onto, for example, the emitting surface of a phosphor becomes larger than a total internal reflection critical angle, the light is not emitted, but reflected inside the phosphor, leading to a decrease in an extraction efficiency of light. In addition, in certain semiconductor light emitting elements, such as LEDs, electrode patterns can be distinguished from the emitting surfaces thereof. There is the fear that the electrode shape of such a light emitting element may generate a light intensity unevenness.

Accordingly, the present invention has been made to solve the aforementioned problems and a purpose of the invention is to achieve a high extraction efficiency of the light from a light emitting module and to suppress a light intensity unevenness.

### Means for Solving the Problem

In order to solve the aforementioned problems, a light emitting module according to an embodiment of the present invention comprises: a light emitting element; and a transparent light wavelength conversion ceramic, which has 40 percent or more of the total light transmittance of the light with a wavelength within the conversion wavelength range, configured to convert the wavelength of the light emitted by the light emitting element and to emit the light from the emitting surface. An electrode pattern to which a current for light emission is supplied is formed on the emitting surface, and the light wavelength conversion ceramic has a plurality of protruding portions provided on the emitting surface at an arrangement interval smaller than the repeating pattern interval in the electrode pattern.

According to the embodiment, the light reflected toward the light emitting element, without being emitted from the emitting surface of the light wavelength conversion ceramic, can be first suppressed by providing protruding portions on the light wavelength conversion ceramic, as stated above, thereby allowing a high extraction efficiency of light to be achieved. Further, a light intensity unevenness generated by the electrode pattern can be suppressed by making the arrangement interval of the protruding portions to be smaller than the repeating pattern interval in the electrode pattern.

Each of the plurality of protruding portions may be formed into a hemispherical shape. As a result of intensive research and development by the present inventors, it has been found that a higher extraction efficiency of light can be achieved by forming the protruding portion into a spherical shape. Therefore, according to the embodiment, it becomes possible to provide a light emitting module that emits light with a higher light intensity.

Alternatively, each of the plurality of protruding portions may be formed into a shape obtained by cutting a cylinder with a plane parallel to the central axis thereof, and be arranged such that the curved portion thereof forms the emitting surface. Alternatively, each of the plurality of protruding portions may be formed into a triangular prism shape and be arranged such that two side surfaces thereof form the emitting surface.

Another embodiment of the present invention is a lamp unit. The lamp unit comprises: a light emitting module including a light emitting element, and a transparent light wavelength conversion ceramic, which has 40 percent or more of the total light transmittance of the light with a wavelength within the conversion wavelength range, that converts the wavelength of the light emitted by the light emitting element and emits the light from the emitting surface; and an optical member configured to collect the light emitted by the light emitting module. An electrode pattern to which a current for light emission is supplied is formed on the emitting surface, and the light wavelength conversion ceramic has a plurality of protruding portions provided on the emitting surface at an arrangement interval smaller than the repeating pattern interval in the electrode pattern.

When a light emitting element is used as a light source, reduction in a light intensity unevenness thereof becomes a particularly important challenge. According to the embodiment, it becomes possible to provide a lamp unit with a higher light intensity and a lower light intensity unevenness by using a light emitting module in which an extraction efficiency of light is high and a light intensity unevenness is suppressed, as stated above.

Still another embodiment of the present invention is a light emitting module. The light emitting module comprises: a light emitting element; and a transparent light wavelength conversion ceramic, which has 40 percent or more of the total light transmittance of the light with a wavelength within the conversion wavelength range, configured to convert the wavelength of the light emitted by the light emitting element and to emit the light from the emitting surface. The light wavelength conversion ceramic has a plurality of protruding portions provided on the emitting surface at an arrangement interval of 300 μm.

As a result of intensive research and development by the present inventors, it has been found that a higher extraction efficiency of light can be achieved by making the arrangement interval of protruding portions to be smaller than or equal to 300 μm. Therefore, according to the embodiment, a light emitting module with a high light intensity can be achieved. Even in this case, each of the plurality of protruding portions may also be formed into a spherical shape. Alternatively, each of the plurality of protruding portions may be formed into a shape obtained by cutting a cylinder with a plane parallel to the central axis thereof, and be arranged such that the curved portion thereof forms the emitting surface. Alternatively, each of the plurality of protruding portions may be formed into a triangular prism shape and be arranged such that two side surfaces thereof form the emitting surface.

Still another embodiment of the present invention is a lamp unit. The lamp unit comprises: a light emitting module including a light emitting element, and a transparent light wavelength conversion ceramic, which has 40 percent or more of the total light transmittance of the light with a wavelength within the conversion wavelength range, that converts the wavelength of the light emitted by the light emitting element and emits the light from the emitting surface; and an optical member configured to collect the light emitted by the light emitting module. The light wavelength conversion ceramic has a plurality of protruding portions provided on the emitting surface at an arrangement interval of 300 μm. According to the embodiment, it becomes possible to provide a lamp unit with a higher light intensity by using a light emitting module with a high extraction efficiency of light, as stated above.

### ADVANTAGE OF THE INVENTION

According to the present invention, a high extraction efficiency of the light from a light emitting element can be achieved and a light intensity unevenness can be suppressed.

### BRIEF DESCRIPTION OF THE DRAWINGS

FIG. 1 is a sectional view illustrating the configuration of an automotive headlamp according to a first embodiment;

FIG. 2 is a view illustrating the configuration of a light emitting module substrate according to the first embodiment;

FIG. 3(a) is a perspective view illustrating the configuration of a light emitting module according to the first embodiment;

FIG. 3(b) is a view in which FIG. 3(a) is viewed from Viewpoint P;

FIG. 4(a) is a perspective view illustrating the configuration of a light emitting module according to a second embodiment;

FIG. 4(b) is a view in which FIG. 4(a) is viewed from Viewpoint Q;

FIG. 5(a) is a perspective view illustrating the configuration of a light emitting module according to a third embodiment;

FIG. 5(b) is a view in which FIG. 5(a) is viewed from Viewpoint R;

FIG. 6(a) is a perspective view illustrating the configuration of a light emitting module according to a fourth embodiments; and

FIG. 6(b) is a view in which FIG. 6(a) is viewed from Viewpoint S.

### REFERENCE NUMERALS

10 AUTOMOTIVE HEADLAMP

16 LAMP UNIT

30 PROJECTION LENS

34 REFLECTOR

40 LIGHT EMITTING MODULE

44 SUBSTRATE

48 SEMICONDUCTOR LIGHT EMITTING ELEMENT

48 LIGHT EMITTING SURFACE

52 LIGHT WAVELENGTH CONVERSION MEMBER

52 EMITTING SURFACE

52B PROTRUDING PORTION

### BEST MODE FOR CARRYING OUT THE INVENTION

Preferred embodiments of the present invention will now be described in detail with reference to accompanying drawings.

### First Embodiment

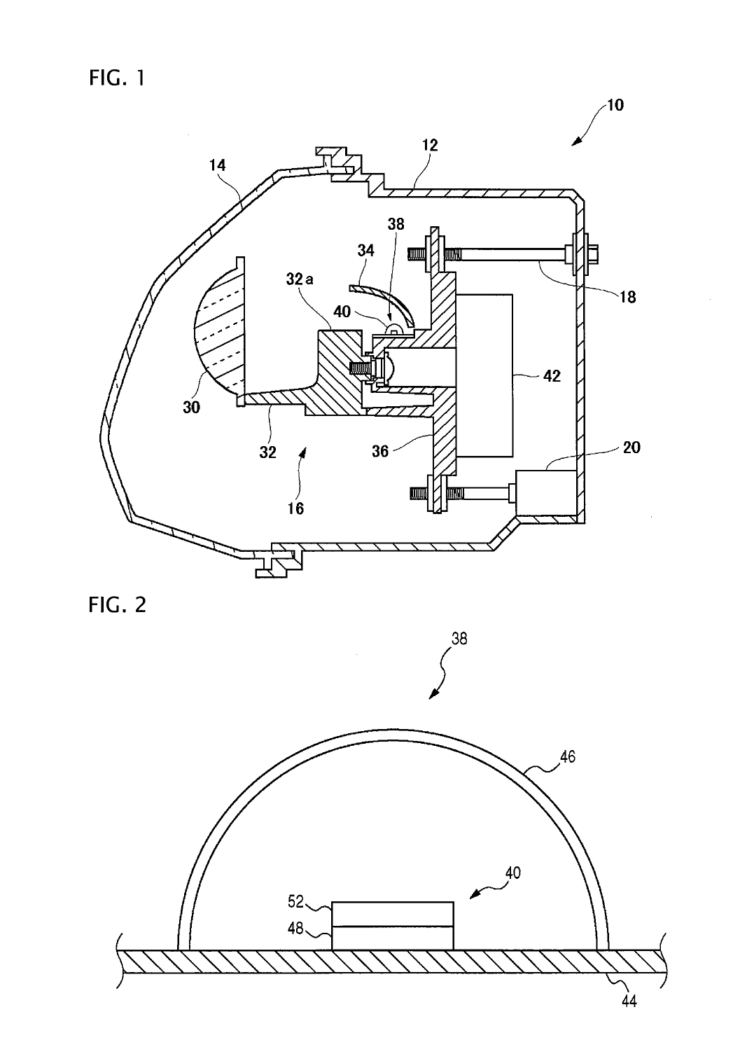

FIG. 1 is a sectional view illustrating the configuration of an automotive headlamp 10 according to a first embodiment. The automotive headlamp 10 has a lamp body 12, a front cover 14, and a lamp unit 16. Hereinafter, descriptions will be made, assuming that the left side in FIG. 1 is the front of the lamp and the right side therein is the back thereof. In addition, when viewing the front of the lamp, the right side is referred to as the right side of the lamp and the left side as the left side thereof. FIG. 1 illustrates the cross section of the automotive headlamp 10 cut by the vertical plane including the light axis of the lamp unit 16, when viewed from the left side of the lamp. When the automotive headlamp 10 is to be mounted in a vehicle, the automotive headlamps 10, which are formed symmetrically with each other, are provided in the left and right front portions of the vehicle, respectively. FIG. 1 illustrates the configuration of either of the left and right automotive headlamps 10.

The lamp body 12 is formed into a box shape having an opening. The front cover 14 is formed into a bow shape with a resin having translucency or glass. The front cover 14 is installed such that the edge thereof is attached to the opening of the lamp body 12. In such a manner, a lamp chamber is formed in the area covered with the lamp body 12 and the front cover 14.

The lamp unit 16 is arranged in the lamp chamber. The lamp unit 16 is fixed to the lamp body 12 with aiming screws 18. The aiming screw 18 in the lower portion is configured to be rotatable by an operation of a leveling actuator 20. Accordingly, the light axis of the lamp unit 16 can be moved in the up-down direction by operating the leveling actuator 20.

The lamp unit 16 has a projection lens 30, a support member 32, a reflector 34, a bracket 36, a light emitting module substrate 38, and a radiating fin 42. The projection lens 30 is composed of a plano-convex aspheric lens, the front surface of which is convex-shaped and the back surface of which is flat-shaped, and projects a light source image that is formed on the back focal plane toward the front of the vehicle as an inverted image. The support member 32 supports the projection lens 30. A light emitting module 40 is provided on the light emitting module substrate 38. The reflector 34 reflects the light emitted from the light emitting module 40 to form the light source image on the back focal plane of the projection lens 30. As stated above, the reflector 34 and the projection lens 30 function as optical members that collect the light emitted by the light emitting module 40 toward the front of the lamp. The radiating fin 42 is installed onto the back surface of the bracket 36 to radiate the heat mainly generated by the light emitting module 40.

A shade 32a is formed on the support member 32. The automotive headlamp 10 is used as a light source for low-beam, and the shade 32a forms, in front of the vehicle, a cut-off line in the light distribution pattern for low-beam by shielding part of the light that has been emitted from the light emitting module 40 and reflected by the reflector 34. Because the light distribution pattern for low-beam is publicly known, descriptions thereof will be omitted.

FIG. 2 is a view illustrating the configuration of the light emitting module substrate 38 according to the first embodiment. The light emitting module substrate 38 has the light emitting module 40, a substrate 44, and a transparent cover 46. The substrate 44 is a printed circuit board, and the light emitting module 40 is attached to the upper surface thereof. The light emitting module 40 is covered with the colorless transparent cover 46. In the light emitting module 40, a semiconductor light emitting element 48 is attached directly on the substrate 44 and a light wavelength conversion member 52 is arranged on the semiconductor light emitting element 48.

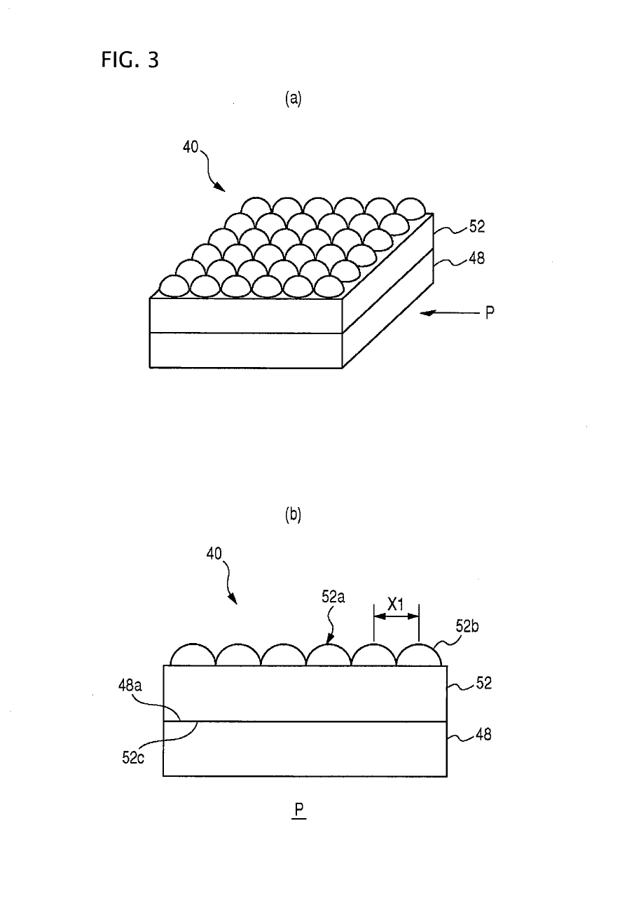

FIG. 3(a) is a perspective view illustrating the configuration of the light emitting module 40 according to the first embodiment, and FIG. 3(b) is a view in which FIG. 3(a) is viewed from Viewpoint P. Hereinafter, the configuration of the light emitting module 40 will be described with reference to both FIG. 3(a) and FIG. 3(b). The semiconductor light emitting element 48 is composed of an LED element. In the first embodiment, a blue LED mainly emitting the light with a blue wavelength is adopted as the semiconductor light emitting element 48. Specifically, the semiconductor light emitting element 48 is composed of an InGaN LED element that is formed by making an InGaN semiconductor layer undergo crystal growth. The semiconductor light emitting element 48 is formed, for example, as a chip of 1 mm×1 mm and is provided such that the central wavelength of the emitted blue light is made to be 470 nm. It is needless to say that the configuration of the semiconductor light emitting element 48 and the wavelength of the emitted light are not limited to what have been stated above.

A vertical chip type semiconductor light emitting element is adopted as the semiconductor light emitting element 48 according to the first embodiment. The vertical chip type semiconductor light emitting element is configured by forming an N-type electrode on the surface of the semiconductor light emitting element on the side to be attached to the substrate, and by laminating an N-type semiconductor, a P-type semiconductor, and further a P-type electrode thereon. Accordingly, an electrode, which is a P-type electrode formed of a conductive material, is provided on the upper surface of the semiconductor light emitting element 48, i.e., on the surface near to the light emitting surface thereof. Because such the semiconductor light emitting element 48 is publicly known, further descriptions thereof will be omitted. It is needless to say that the semiconductor light emitting element 48 is not limited to a vertical chip type, and, for example, a face-up type semiconductor light emitting element may be adopted.

An Au wire is bonded to the electrode. In addition, a notch for bonding the Au wire to the electrode may be provided in the light wavelength conversion member 52. A current necessary for light emission is supplied to the electrode via the Au wire. Alternatively, for example, an aluminum wire, copper foil, or aluminum ribbon wire may be used instead of the Au wire.

The light wavelength conversion member 52 is so-called luminescence ceramic or fluorescent ceramic, and can be obtained by sintering a ceramic green body made of YAG (Yttrium Aluminum Garnet) powder that is a phosphor to be excited by blue light. Because a method of manufacturing such light wavelength conversion ceramic is publicly known, detailed descriptions thereof will be omitted.

The light wavelength conversion member 52 thus obtained converts the wavelength of the blue light mainly emitted by the semiconductor light emitting element 48 and emits yellow light. Accordingly, synthesized light made from both the blue light that has transmitted the light wavelength conversion member 52 as it is and the yellow light whose wavelength has been converted by the light wavelength conversion member 52 is emitted by the light emitting module 40. Thus, it becomes possible to emit white light from the light emitting module 40.

In addition, a transparent light wavelength conversion member is adopted as the light wavelength conversion member 52. The “transparent” in the first embodiment means that the total light transmittance of the light within a conversion wavelength range is 40 percent or more. As a result of intensive research and development by the present inventors, it has been found that, when the light wavelength conversion member 52 is so transparent that the total light transmittance of the light within a conversion wavelength range is 40 percent or more, the wavelength of light can be appropriately converted by the light wavelength conversion member 52 and a decrease in the light intensity of the light transmitting the light wavelength conversion member 52 can be appropriately suppressed. Accordingly, the light emitted by the semiconductor light emitting element 48 can be more efficiently converted by making the light wavelength conversion member 52 to be transparent, as stated above.

In addition, the light wavelength conversion member 52 is composed of an inorganic substance free of an organic binder such that the durability thereof is enhanced in comparison with the case where an organic substance, such as an organic binder, is contained. Accordingly, it becomes possible to supply the power of, for example, 1 W or more to the light emitting module 40, and hence the luminance, light intensity, and luminous flux of the light emitted by the light emitting module 40 can be enhanced.

Alternatively, a semiconductor light emitting element mainly emitting light with a wavelength other than blue may be adopted as the semiconductor light emitting element 48. Also in this case, a light wavelength conversion member that converts the wavelength of the light mainly emitted by the semiconductor light emitting element 48 is adopted as the light wavelength conversion member 52. Also in this case, the light wavelength conversion member 52 may convert the wavelength of the light emitted by the semiconductor light emitting element 48 so as to emit the light with a wavelength of white light or near to white light by combining with the light with the wavelength mainly emitted by the semiconductor light emitting element 48.

When the wavelength of the light emitted by the semiconductor light emitting element 48 is converted by the light wavelength conversion member 52, as stated above, there is the possibility that an extraction efficiency of light may be decreased with the light being reflected toward the semiconductor light emitting element 48, without being emitted from the emitting surface of the light wavelength conversion member 52. Also, there is the possibility that a light intensity unevenness, generated by the electrode pattern formed on the light emitting surface 48a of the semiconductor light emitting element 48, may not be reduced even via the light wavelength conversion member 52, because the light wavelength conversion member 52 is transparent, as stated above. In particular, when the light emitting module 40 is used as a light source for a lamp unit, etc., reduction in the light intensity unevenness by the light emitting module 40 itself becomes a major challenge, because the light intensity unevenness by the light emitting module 40 itself leads to an illuminance unevenness in an area to which light is emitted.

Accordingly, in the first embodiment, a plurality of protruding portions 52b are provided on the emitting surface 52a of the light wavelength conversion member 52 in order to enhance an extraction efficiency of light and to reduce a light intensity unevenness. By providing the protruding portions 52b, as stated above, a decrease in an extraction efficiency of light, occurring because the light incident from the semiconductor light emitting element 48 is again reflected toward the semiconductor light emitting element 48 without being emitted from the emitting surface 52a, can be suppressed.

Each of the plurality of protruding portions 52b is formed into a hemispherical shape. As a result of intensive research and development by the present inventors, it has been confirmed that an extraction efficiency of light can be more enhanced by forming the protruding portion 52b into a hemispherical shape, in comparison with the case where the protruding portion 52b is formed into another shape.

In the semiconductor light emitting element 48, an electrode pattern to which a current for light emission is supplied is formed on the light emitting surface 48a. Accordingly, the plurality of protruding portions 52b are provided at an arrangement interval X1 smaller than the repeating pattern interval in the electrode pattern. By making the arrangement interval X1 to be smaller than the repeating pattern interval in the electrode pattern, as stated above, a light intensity unevenness generated by the electrode pattern can be suppressed. It is needless to say that a surface on which the electrode pattern in the semiconductor light emitting element 48 is provided is not limited to the light emitting surface 48a.

In the first embodiment, the arrangement interval X1 is made to be 1 μm or more and 300 μm or less. As a result of intensive research and development by the present inventors, it has been confirmed that an extraction efficiency of light can be enhanced and a light intensity unevenness can be suppressed by arranging the protruding portions 52b as stated above. It has also been confirmed that better results can be acquired in the extraction efficiency of light and the suppression of a light intensity unevenness by making the arrangement interval X1 to be 1 μm or more and 100 μm or less. Alternatively, the arrangement interval X1 may be less than 1 μm. In addition, the width of the protruding portion 52b is made to be the same as the arrangement interval X1 in the first embodiment. Accordingly, the width thereof is made to be 1 μm or more and 300 μm or less. Alternatively, the width thereof may be made to be smaller than the arrangement interval X1.

In manufacturing the light emitting module 40, the light wavelength conversion member 52 is first manufactured by cutting, into the same size as the light emitting surface 48a of the semiconductor light emitting element 48 with dicing, etc., a material for the light wavelength conversion member 52, which has been formed such that the length of the edge thereof is two times or more larger than the light emitting surface 48a of the semiconductor light emitting element 48 and on one of the surfaces of which the plurality of protruding portions 52b are provided. The incident surface 52c of the light wavelength conversion member 52 thus manufactured is fixed to the light emitting surface 48a of the semiconductor light emitting element 48 by adhesion, etc.

Alternatively, a space maybe provided between the light emitting surface 48a of the semiconductor light emitting element 48 and the incident surface 52c of the light wavelength conversion member 52. Thereby, the Au wire, etc., bonded to the electrode provided on the light emitting surface 48a of the semiconductor light emitting element 48 can be easily pulled around. The space may be provided across the whole area of the light emitting surface 48a of the semiconductor light emitting element 48, or maybe provided such that at least part of the electrode provided on the light emitting surface 48a of the semiconductor light emitting element 48 is exposed. In addition, a reflective film or a reflective member may be fixed to the side surface of the light wavelength conversion member 52. Thereby, it becomes possible to suppress the leak of light from the side surface of the light wavelength conversion member 52 and accordingly to emit more light from the emitting surface 52a.

### Second Embodiment

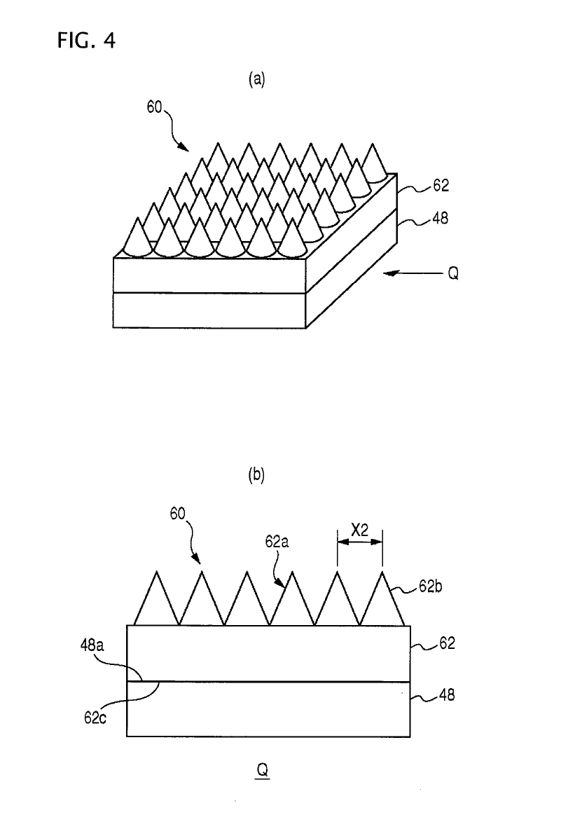

FIG. 4(a) is a perspective view illustrating the configuration of a light emitting module 60 according to a second embodiment, and FIG. 4(b) is a view in which FIG. 4(a) is viewed from Viewpoint Q. Hereinafter, the configuration of the light emitting module 60 will be described with reference to both FIG. 4(a) and FIG. 4(b). The configuration of an automotive headlamp 10 is the same as that of the first embodiment, except that the light emitting module 60 is provided instead of the light emitting module 40. Hereinafter, the parts similar to the first embodiment will be denoted with the same reference numerals and descriptions thereof will be omitted.

The light emitting module 60 is configured in the same way as the light emitting module 40 according to the first embodiment, except that a light wavelength conversion member 62 is provided instead of the light wavelength conversion member 52. The light wavelength conversion member 62 is the same as the light wavelength conversion member 52 in that the incident surface 62c thereof is fixed to the light emitting surface 48a of a semiconductor light emitting element 48 by adhesion, etc. Alternatively, a space may be provided between the light emitting surface 48a of the semiconductor light emitting element 48 and the incident surface 62c of the light wavelength conversion member 62.

A plurality of protruding portions 62b for suppressing a decrease in an extraction efficiency of light are provided on the emitting surface 62a of the light wavelength conversion member 62. Each of the plurality of protruding portions 62b is formed into a corn shape. As a result of intensive research and development by the present inventors, it has been confirmed that an extraction efficiency of light can also be enhanced by forming the protruding portion 62b into a corn shape. Alternatively, the protruding portion 62b may be formed into another pyramidal shape, such as a quadrangular pyramid or triangular pyramid.

The plurality of protruding portions 62b are provided at an arrangement interval X2 smaller than the repeating pattern interval in the electrode pattern. It has been confirmed that good results can be acquired in an extraction efficiency of light and suppression of a light intensity unevenness by making the arrangement interval X2 to be 1 μm or more and 300 μm or less. It has also been confirmed that better results can be acquired in the extraction efficiency of light and the suppression of a light intensity unevenness by making the arrangement interval X2 to be 1 μm or more and 100 μm or less. Alternatively, the arrangement interval X2 may be less than 1 μm. In addition, the width of the protruding portion 62b is made to be the same as the arrangement interval X2 in the second embodiment. Accordingly, the width thereof is made to be 1 μm or more and 300 μm or less. Alternatively, the width thereof may be made to be smaller than the arrangement interval X2.

### Third Embodiment

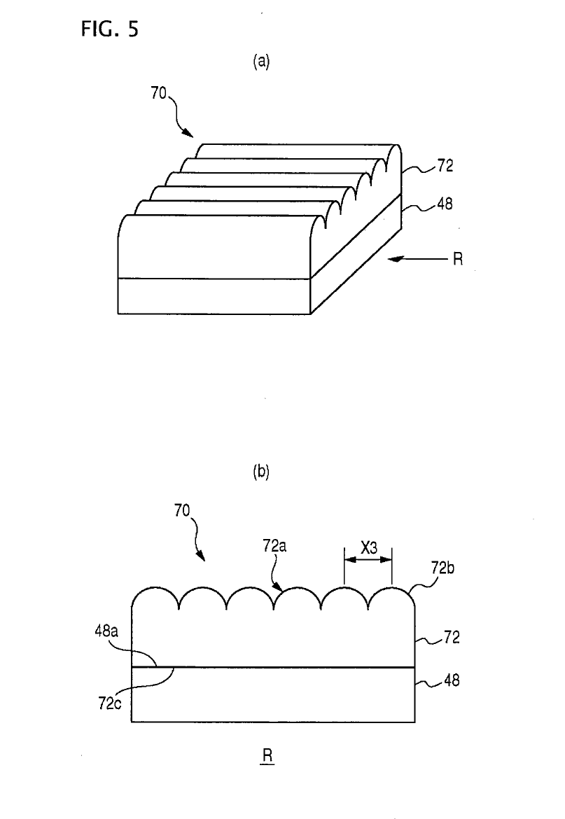

FIG. 5(a) is a perspective view illustrating the configuration of a light emitting module 70 according to a third embodiment, and FIG. 5(b) is a view in which FIG. 5(a) is viewed from Viewpoint R. Hereinafter, the configuration of the light emitting module 70 will be described with reference to both FIG. 5(a) and FIG. 5(b). The configuration of an automotive headlamp 10 is the same as that of the first embodiment, except that the light emitting module 70 is provided instead of the light emitting module 40. Hereinafter, the parts similar to the first embodiment will be denoted with the same reference numerals and descriptions thereof will be omitted.

The light emitting module 70 is configured in the same way as the light emitting module 40 according to the first embodiment, except that a light wavelength conversion member 72 is provided instead of the light wavelength conversion member 52. The light wavelength conversion member 72 is the same as the light wavelength conversion member 52 in that the incident surface 72c thereof is fixed to the light emitting surface 48a of a semiconductor light emitting element 48 by adhesion, etc. Alternatively, a space may be provided between the light emitting surface 48a of the semiconductor light emitting element 48 and the incident surface 72c of the light wavelength conversion member 72.

A plurality of protruding portions 72b for suppressing a decrease in an extraction efficiency of light are provided on the emitting surface 72a of the light wavelength conversion member 72. Each of the plurality of protruding portions 72b is formed such that the cross section thereof has a semicircular shape and extends to be parallel to the emitting surface 72a. Specifically, each of the plurality of protruding portions 72b is formed into a shape obtained by cutting a cylinder with a plane parallel to the central axis thereof, and is arranged such that the curved portion thereof forms the emitting surface 72a. Alternatively, each of the plurality of protruding portions 72b may be formed into a shape obtained by cutting a cylinder with a plane including the central axis thereof. Each of the plurality of protruding portions 72b is arranged such that the axial direction thereof is parallel to those of other protruding portions and the arrangement interval between any two protruding portions adjacent to each is approximately the same as an arrangement interval X3.

The plurality of protruding portions 72b are provided at the arrangement interval X3 smaller than the repeating pattern interval in the electrode pattern. It has been confirmed that good results can be acquired in an extraction efficiency of light and suppression of a light intensity unevenness by making the arrangement interval X3 to be 1 μm or more and 300 μm or less. It has also been confirmed that better results can be acquired in the extraction efficiency of light and the suppression of a light intensity unevenness by making the arrangement interval X3 to be 1 μm or more and 100 μm or less. Alternatively, the arrangement interval X3 may be less than 1 μm. In addition, the width of the protruding portion 72b is made to be the same as the arrangement interval X3 in the third embodiment. Accordingly, the width of the protruding portion 72b is made to be 1 μm or more and 300 μm or less. Alternatively, the width of the protruding portion 72b may be made to be smaller than the arrangement interval X3.

### Fourth Embodiment

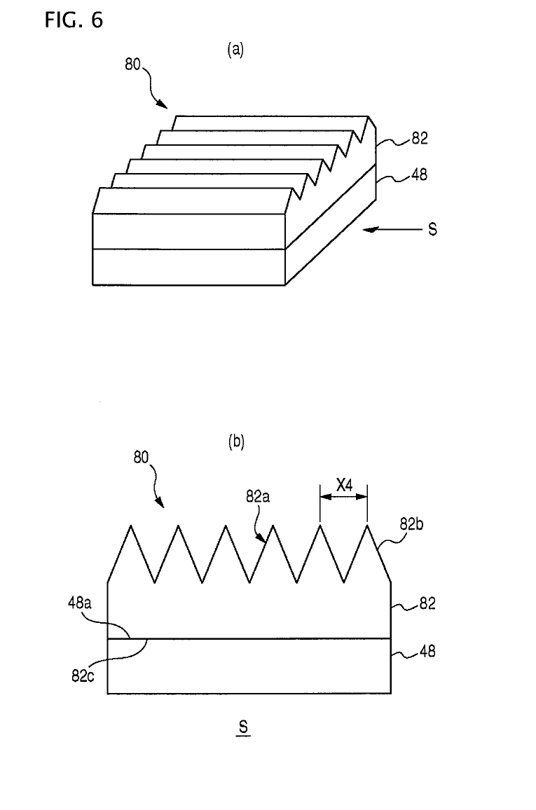

FIG. 6(a) is a perspective view illustrating the configuration of a light emitting module 80 according to a fourth embodiment, and FIG. 6(b) is a view in which FIG. 6(a) is viewed from Viewpoint S. Hereinafter, the configuration of the light emitting module 80 will be described with reference to both FIG. 6(a) and FIG. 6(b). The configuration of an automotive headlamp 10 is the same as that of the first embodiment, except that the light emitting module 80 is provided instead of the light emitting module 40. Hereinafter, the parts similar to the first embodiment will be denoted with the same reference numerals and descriptions thereof will be omitted.

The light emitting module 80 is configured in the same way as the light emitting module 40 according to the first embodiment, except that a light wavelength conversion member 82 is provided instead of the light wavelength conversion member 52. The light wavelength conversion member 82 is the same as the light wavelength conversion member 52 in that the incident surface 82c thereof is fixed to the light emitting surface 48a of a semiconductor light emitting element 48 by adhesion, etc. Alternatively, a space may be provided between the light emitting surface 48a of the semiconductor light emitting element 48 and the incident surface 82c of the light wavelength conversion member 82.

A plurality of protruding portions 82b for suppressing a decrease in an extraction efficiency of light are provided on the emitting surface 82a of the light wavelength conversion member 82. Each of the plurality of protruding portions 82b is formed such that the cross section thereof has a triangular shape and extends to be parallel to the emitting surface 82a. Specifically, each of the plurality of protruding portions 82b is formed into a triangular prism shape, and is arranged such that two side surfaces of the three side surfaces thereof form the emitting surface 82a. Each of the plurality of protruding portions 82b is arranged such that the axial direction thereof is parallel to those of other protruding portions and the arrangement interval between any two protruding portions adjacent to each is approximately the same as an arrangement interval X4.

The plurality of protruding portions 82b are provided at the arrangement interval X4 smaller than the repeating pattern interval in the electrode pattern. It has been confirmed that good results can be acquired in an extraction efficiency of light and suppression of a light intensity unevenness by making the arrangement interval X4 to be 1 μm or more and 300 μm or less. It has also been confirmed that better results can be acquired in the extraction efficiency of light and the suppression of a light intensity unevenness by making the arrangement interval X4 to be 1 μm or more and 100 μm or less. Alternatively, the arrangement interval X4 may be less than 1 μm. In addition, the width of the protruding portion 82b is made to be the same as the arrangement interval X4 in the fourth embodiment. Accordingly, the width of the protruding portion 82b is made to be 1 μm or more and 300 μm or less. Alternatively, the width of the protruding portion 82b may be made to be smaller than the arrangement interval X4.

The present invention should not be limited to the above embodiments, and variations in which each component of the embodiments is appropriately combined are also effective as embodiments of the invention. Various modifications, such as design modifications, can be made with respect to the above embodiments based on the knowledge of those skilled in the art. Such modified embodiments can also fall in the scope of the invention. Hereinafter, such variations will be described.

In a variation, an optical filter is provided between the light emitting surface of the semiconductor light emitting element and the incident surface of the light wavelength conversion member in each of the above embodiments. The optical filter transmits the blue light mainly emitted by the semiconductor light emitting element and reflects the yellow light obtained by converting the wavelength of the blue light by the light wavelength conversion member and mainly emitted thereby. By providing an optical filter, as stated above, the light emitted by the semiconductor light emitting element can be used efficiently, and hence it becomes possible to suppress a decrease in the light intensity or luminance of the light emitted by the light emitting module.

### INDUSTRIAL APPLICABILITY

The present invention is applicable to a light emitting module, and a lamp unit comprising the light emitting module.

1. A light emitting module comprising:
a light emitting element; and
a transparent light wavelength conversion ceramic, which has 40 percent or more of the total light transmittance of the light with a wavelength within the conversion wavelength range, configured to convert the wavelength of the light emitted by the light emitting element and to emit the light from the emitting surface, wherein
an electrode pattern to which a current for light emission is supplied is formed on the emitting surface, and wherein
the light wavelength conversion ceramic has a plurality of protruding portions provided on the emitting surface at an arrangement interval smaller than the repeating pattern interval in the electrode pattern.

2. The light emitting module according to claim 1, wherein
each of the plurality of protruding portions is formed into a hemispherical shape.

3. The light emitting module according to claim 1, wherein
each of the plurality of protruding portions is formed into a pyramidal shape.

4. The light emitting module according to claim 1, wherein
each of the plurality of protruding portions is formed into a shape obtained by cutting a cylinder with a plane parallel to the central axis thereof, and is arranged such that the curved portion thereof forms the emitting surface.

5. The light emitting module according to claim 1, wherein
each of the plurality of protruding portions is formed into a triangular prism shape, and arranged such that two side surfaces thereof form the emitting surface.

6. A lamp unit comprising:
a light emitting module including a light emitting element, and a transparent light wavelength conversion ceramic, which has 40 percent or more of the total light transmittance of the light with a wavelength within the conversion wavelength range, that converts the wavelength of the light emitted by the light emitting element and emits the light from the emitting surface; and
an optical member configured to collect the light emitted by the light emitting module, wherein
an electrode pattern to which a current for light emission is supplied is formed on the emitting surface, and wherein
the light wavelength conversion ceramic has a plurality of protruding portions provided on the emitting surface at an arrangement interval smaller than the repeating pattern interval in the electrode pattern.

7. A light emitting module comprising:
a light emitting element; and
a transparent light wavelength conversion ceramic, which has 40 percent or more of the total light transmittance of the light with a wavelength within the conversion wavelength range, configured to convert the wavelength of the light emitted by the light emitting element and to emit the light from the emitting surface, wherein
the light wavelength conversion ceramic has a plurality of protruding portions provided on the emitting surface at an arrangement interval of 300 μm or less.

8. The light emitting module according to claim 7, wherein
each of the plurality of protruding portions is formed into a hemispherical shape.

9. The light emitting module according to claim 7, wherein
each of the plurality of protruding portions is formed into a pyramidal shape.

10. The light emitting module according to claim 7, wherein
each of the plurality of protruding portions is formed into a shape obtained by cutting a cylinder with a plane parallel to the central axis thereof, and is arranged such that the curved portion thereof forms the emitting surface.

11. The light emitting module according to claim 7, wherein
each of the plurality of protruding portions is formed into a triangular prism shape, and is arranged such that two side surfaces thereof form the emitting surface.

12. A lamp unit comprising:
a light emitting module including a light emitting element, and a transparent light wavelength conversion ceramic, which has 40 percent or more of the total light transmittance of the light with a wavelength within the conversion wavelength range, that converts the wavelength of the light emitted by the light emitting element and emits the light from the emitting surface; and
an optical member configured to collect the light emitted by the light emitting module, wherein
the light wavelength conversion ceramic has a plurality of protruding portions provided on the emitting surface at an arrangement interval of 300 μm or less.
